(19) United States
(12) Patent Application Publication
(10) Pub. No.: US 2004/0201952 A1
(43) Pub. Date: Oct. 14, 2004

(54) PCMCIA card converter connector

(76) Inventor: Anderson Lin, Hsin Tien City (TW)

Correspondence Address: D&C Technology Co., Ltd., P.O. Box No. 6-57, Junghe, Taipei, 235, TW

(21) Appl. No.: 10/411,260

(22) Filed: Apr. 11, 2003

(51) Int. Cl. H05K 5/00

(52) U.S. Cl. 361/679

(57) ABSTRACT

A PCMCIA card converter connector includes a PC card casing; a connector casing for connecting to the PC card casing and having an accommodating room formed at an interior thereof; a plurality of USB connector sockets or at least one IEEE1394 connector socket disposed at one end face of the connector and are for inserting USB connectors or IEEE1394 connectors; and a connector circuit board disposed in the accommodating room and provided with a PCMCIA connector interface at a rear end portion thereof. The USB or IEEE1393 connector sockets are electrically connected to a front end portion of the connector circuit board for converting electric signals of the connector into electric signals of the PCMCIA connecter interface, thereby accomplishing an object of converting a PCMCIA card into a USB connector or an IEEE1394 connector.

### BACKGROUND OF THE INVENTION

(a) Field of the Invention

The invention relates to a PCMCIA card converter connector, and more particularly, to a converter connector using a PCMCIA (Personal Computer Memory Card International Association) card that converts into a USB or IEEE1394 connector for expanding peripherals linked to a computer.

(b) Description of the Prior Art

Computers are a necessity in the everyday life because of the conveniences and powerful functions that they provide. Current computers include connector ports such as RS-232, PCMCIA, USB and IEEE1394 for expanding by connecting to various computer peripherals namely scanners, printers, hard disks or CD ROMs.

In a prior art, PCMCIA, generally referred to as a PCMCIA connector, is applied in connectors of computers and computer peripherals; an integrated circuit conforming to this specification is named as a PCMCIA card, which shall be called as a PC card below, and a slot conforming to this specification is named as a PCMCIA slot. Presently most notebook computers are provided with PCMCIA slots for inserting PC cards. Because notebook computers are restricted by the comparatively smaller volumes thereof and peripherals must be externally connected, PC cards have become the best connectors by eliminating troubles of having users to carry bulky peripherals. Currently on the market, types of PC cards include data cards, network interface cards and hard disk cards are available.

Other connectors like USB connectors and IEEE1394 connectors offering advantages as having high-speed and being able to plug-and-play are also well-known. However, these connectors may not be provided in sufficient numbers being again restrained by volumes of notebook computers, and therefore the industrialists have developed so-called external expansion devices for expanding USB or IEEE1394 connectors that are further link peripherals such as hard disks and CD ROMs. Yet, these external expansion devices come in large sizes as well, thus lowering mobility that notebook computers ought to have and unity of the entire equipment; above all, compatibilities thereof may not be fully guaranteed either.

### SUMMARY OF THE INVENTION

In the view of the above, the primary object of the invention is to provide a PCMCIA card converter connector capable of effectively overcoming the aforesaid disadvantages. A PCMCIA connector card is converted into a USB or IEEE1394 expansion connector, which forms with a computer as a modularized connector and has an excellence of being able to plug-and-play.

To achieve the above object, the invention provides the following technical means to integrate a PC card into a USB or IEEE1394 expansion connector.

The primary technical characteristic of the invention is to provide a PCMCIA card converter connector comprising a PC card casing having an upper PC card casing and a lower PC card casing; a connector casing having an upper connector casing and a lower connector casing, wherein the upper connector casing is connected to the upper PC card casing, and the lower connector casing is connected to the lower PC card casing, so as to form an accommodating room in the connector casing and the PC card casing; a plurality of A-type USB connector sockets, a B-type USB connector socket or an IEEE1394 connector socket disposed at an end face of the connector casing and for inserting A-type USB connectors, a B-type USB connector or an IEEE1394 connector; a connector circuit board disposed in the accommodating room and having a PCMCIA connector interface provided at a rear end portion thereof, such that electric signals of the USB or IEEE1394 connectors are converted into electric signals of the PCMCIA connector interface by electrically connecting the USB or IEEE1394 connector sockets to a front end portion of the connector circuit board, thereby accomplishing an effect of converting a PC card into a USB connector or an IEEE1394 connector.

The secondary technical characteristic of the invention is to provide the aforesaid PCMCIA card converter connector, wherein end portions at two sides of the upper PC card casing are disposed with an inward concave track further flexibly connected to end portions at two sides of the lower PC card casing, respectively, thereby accomplishing an effect of easily assembling the upper PC card casing to the lower PC card casing.

Another technical characteristic of the invention is to provide the aforesaid PCMCIA card converter connector, wherein a rear end portion of the upper connector casing is provided with at least one extended hitch piece, and a front end portion of the upper PC card casing is provided with at least one opening, such that the hitch piece is hitched in the opening, thereby accomplishing an effect of readily assembling the upper PC card casing to the upper connector casing.

The other technical characteristic of the invention is to provide the aforesaid PCMCIA card converter connector, wherein a PCMCIA connector interface is electrically connected to a rear end portion of the circuit board using a PCMCIA slot, and an elastic fixing plate is provided on the circuit board, thereby accomplishing an effect of stabilizing the PCMCIA connector slot that is further connected to a PCMCIA connecter.

### BRIEF DESCRIPTION OF THE DRAWINGS

FIG. 1 shows an elevational view of the PCMCIA card converter connector according to the invention.

FIG. 2 shows an exploded elevational view of FIG. 1.

FIG. 3 shows a sectional schematic view of FIG. 1 along A-A′.

FIG. 4 shows a sectional schematic view of FIG. 1 along B-B′.

FIG. 5 shows a partial enlarged view illustrating the upper connector casing before being connected to the upper PC card according to the invention.

FIG. 6 shows a partial enlarged view illustrating the upper connector casing after being connected to the upper PC card according to the invention.

### DETAILED DESCRIPTION OF THE PREFERRED EMBODIMENTS

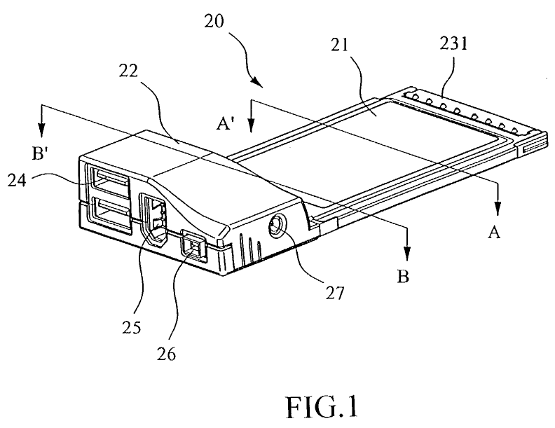

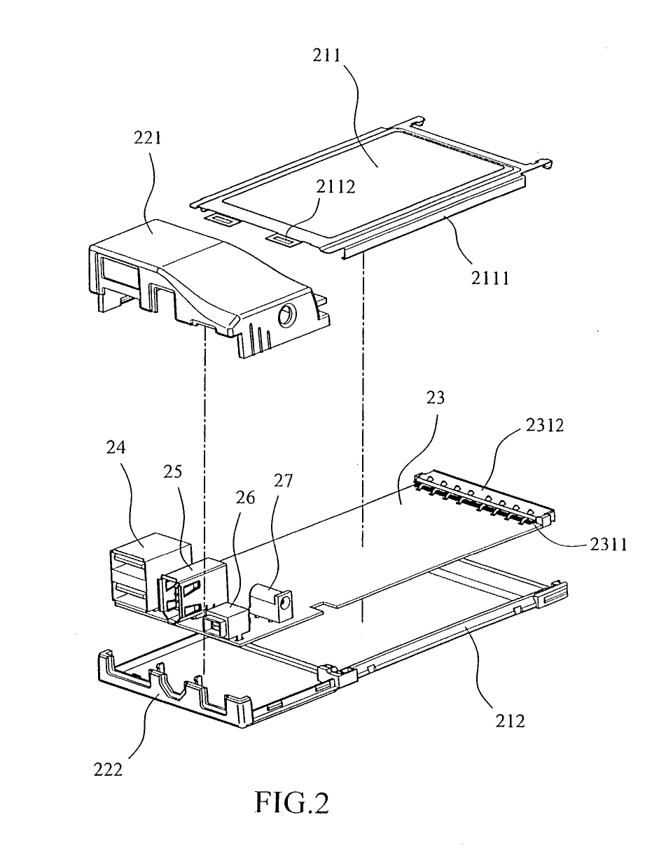

To better understand the techniques, means and effects for achieving the targeted object of the invention, detailed descriptions shall be given with the accompanying drawings hereunder. However, the appended drawings are exemplary for reference only, and the invention shall not be limited therein. Referring to FIGS. 1 and 2 showing an elevational view of the PCMCIA card converter connector according to the invention, and an exploded elevational view of FIG. 1, respectively, the invention converts a PC card used in a personal computer (a notebook computer, for instance) into an expandable A-type USB, B-type USB or IEEE1394 connector 20, which is then placed in a PCMCIA connector of the computer. In this way, the PC card is combined with the notebook computer into one body, and thus creating a unified visual effect. Therefore the invention gives infinite expansion ability by having the connector 20 link to other peripherals.

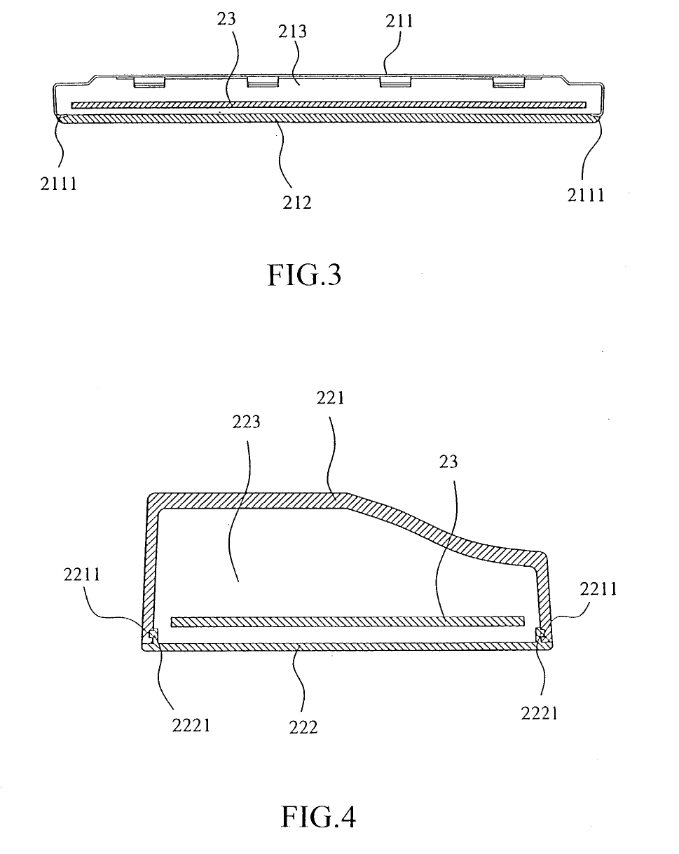

The connector 20 according to the invention includes a PC card casing 21, a connector casing 22 and a connector circuit board 23. Wherein, the PC card casing 21 resembles a PCMCIA card in appearance and has an upper PC card casing 211 and a lower PC card casing 212 that are connected with each other to form an integral, and an interior of the PC card casing 21 is formed as a room for accommodating the connector circuit board 23. Referring to FIG. 3 showing a sectional schematic view of FIG. 1 along A-A′, end portions at two sides of the upper PC card casing 211 are disposed with an inward concave track 2111 further flexibly connected to end portions at two sides of the lower PC card casing 212, respectively, so as to assembly the upper PC card casing 211 to the lower PC card casing 212.

Referring to FIG. 4 showing a sectional schematic view of FIG. 1 along B-B′, wherein the connector casing 22 is similarly formed by connecting an upper connector casing 221 and a lower connector casing 222. End portions of two sides of the upper connector casing 221 are disposed with at least one wedging slot 2211, respectively, and end portions of two sides of the lower connector casing 222 are disposed with at least one wedging fastener 2221, respectively, such that the wedging fasteners 2221 are wedged into the wedging slots 2211 for assembling the upper connector casing 221 to the lower connector casing 222.

Also, the upper connector casing 221 may be connected to the upper PC card casing 211, and the lower connector casing 222 may be connected to the lower PC card casing 212, so that an interior of the connector 22 forms a room 223 in communication with a room 213 of the PC card casing 21 in order to accommodate the circuit board 23.

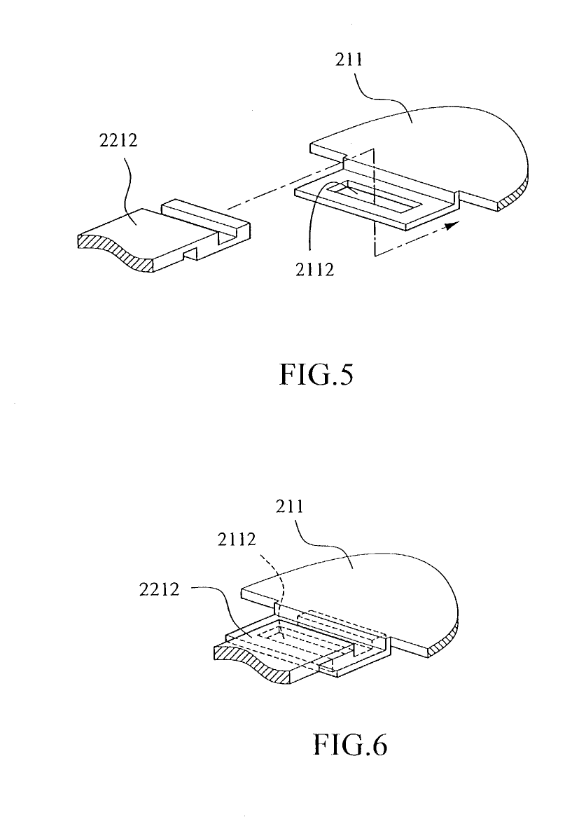

Referring to FIGS. 5 and 6 showing a partial enlarged view illustrating the upper connector casing 221 before being connected to the upper PC card 211, and an enlarged partial view after being connected, respectively, a rear end portion of the upper connector casing 221 is provided with two extended hitch pieces 2212, and a front end portion of the upper PC card casing 211 is provided with two openings 2112, such that the hitch pieces 2212 are hitched in the openings 2112 for assembling the upper PC card casing 211 to the upper connector casing 221. A rear end portion of the lower connector casing 222 is anchored to a front end portion of the lower PC card casing 212, so that the lower connector casing 222 is assembled to the lower PC card casing 212 to form one body.

Referring to FIG. 2 again, a rear end portion of the circuit board 23 is disposed with a PCMCIA connector interface 231 electrically connected to the circuit board 23 using a PMCCIA connector slot 2311. An elastic fixing plate 2312 is provided on the circuit board 23 for stabilizing the PCMCIA connector slot 2311 that is further connected to a PCMCIA connecter 11.

A front portion of the connector circuit board 23 is electrically connected to two A-type USB connector sockets 24, an IEEE1394 connector socket 25, a B-type USB connector socket 26 and a power supply socket 27. The A-type USB connector sockets 24, the IEEE1394 connector socket 25 and the B-type USB connector socket 26 are disposed at the front end portion of the connector casing 22 and are for inserting A-type USB connectors, IEEE1394 connectors and B-type USB connectors.

The power supply socket 27 is disposed an end portion at a right side of the connector casing 22 and is for inserting a direct current power terminal. The connector circuit 23 is utilized to convert electric signals of the A-type USB connector sockets 24, the IEEE1394 connector socket 25 and the B-type USB connector socket 26 to electric signals of the PCMCIA connector interface 231.

It is of course to be understood that the embodiment described herein is merely illustrative of the principles of the invention and that a wide variety of modifications thereto may be effected by persons skilled in the art without departing from the spirit and scope of the invention as set forth in the following claims.

What is claimed is:

1. A PCMCIA card converter connector comprising:
a PC card casing having an upper PC card casing and a lower PC card casing;
a connector casing having an upper connector casing and a lower connector casing, wherein the upper connector casing is connected to the upper PC card casing, and the lower connector casing is connected to the lower PC card casing, so as to form an accommodating room at an interior of the PC card casing;
a plurality of connector sockets disposed at an end face of the connector casing and for inserting connectors; and
a connector circuit board disposed in the accommodating room and having a rear end portion thereof provided with a PCMCIA connector interface, wherein the connector sockets are electrically connected to a front end portion of the connector circuit board for converting electric signals of the connector into electric signals of the PCMCIA connector interface.

2. The PCMCIA card converter connector in accordance with claim 1 further comprising a power supply socket disposed at one end face of the connector casing and for inserting a direct current power supply terminal.

3. The PCMCIA card converter connector in accordance with claim 1, wherein the upper PC card connector further is disposed with an inward concave track further flexibly connected to end portions at two sides of the lower PC card casing, respectively, so as to assemble the upper PC card casing to the lower PC card casing.

4. The PCMCIA card converter connector in accordance with claim 1, wherein end portions of two inner sides of the upper connector casing are disposed with at least one wedging slot, respectively, and end portions of two outer sides of the lower connector casing are disposed with at least one wedging fastener, respectively, such that the wedging fasteners are wedged into the wedging slots for assembling the upper connector casing to the lower connector casing.

5. The PCMCIA card converter connector in accordance with claim 1, wherein a rear end portion of the upper connector casing is provided with at least one extended hitch piece, and a front end portion of the upper PC card casing is provided with at least one opening, such that the hitch piece is hitched in the opening for assembling the upper PC card casing to the upper connector casing.

6. The PCMCIA card converter connector in accordance with claim 1, wherein the connector sockets are A-type USB connector sockets, B-type USB connector sockets or IEEE1394 connector sockets, or all three of the above.
